(19) United States
(12) Patent Application Publication
(10) Pub. No.: US 2020/0403126 A1
(43) Pub. Date: Dec. 24, 2020

(54) Quantum Dot Structure and Method of Producing a Quantum Dot Structure

(71) Applicants: OSRAM Opto Semiconductors GmbH, Regensburg (DE); The Trustees of Columbia University in the City of New York, New York, NY (US)

(72) Inventors: Jonathan Owen, New York, NY (US); Maria J. Anc, Groveland, MA (US); Madis Raukas, Lexington, MA (US); Joseph Treadway, Portland, OR (US); Anindya Swarnakar, Scarborough (CA); Brandon McMurtry, New York, NY (US)

(21) Appl. No.: 16/900,745

(22) Filed: Jun. 12, 2020

Related U.S. Application Data
(60) Provisional application No. 62/865,759, filed on Jun. 24, 2019.

(51) Int. Cl. H01L 33/50; C09K 11/70

(52) U.S. Cl. CPC H01L 33/502; H01L 2933/0041; C09K 11/70; H01L 33/507

(57) ABSTRACT

A quantum dot structure and a method for producing a quantum dot structure are disclosed. In an embodiment the quantum dot structure includes a core comprising a III-V-compound semiconductor material, an intermediate region comprising a III-V-compound semiconductor material at least partially surrounding the core, a shell comprising a III-V-compound semiconductor material at least partially surrounding the core and the intermediate region and a passivation region comprising a II-VI-compound semiconductor material at least partially surrounding the shell.

### CROSS-REFERENCE TO RELATED APPLICATIONS

This application claims the benefit of U.S. Provisional Application No. 62/865,759, filed on Jun. 24, 2019, which application is hereby incorporated herein by reference.

### TECHNICAL FIELD

The present application pertains to a quantum dot (QD) structure and to the synthesis of such a quantum dot structure.

### BACKGROUND

Quantum Dots (QDs) are narrow-band emitters with broad absorption and narrow emission spectra in wavelength range from UV up to NIR depending on their material composition and nanocrystal size.

Cd-containing II-VI quantum dots have attracted and conquered interests of broad academic and R&D communities due to the accessible bench synthesis methods and emission across the full visible range. However, the use of Cd is restricted in many countries, and the allowed level of Cd in devices limits the performance benefit of Cd-based quantum dots. Thus there is the need for efficient non-Cd quantum dots.

### SUMMARY

Embodiments provide an efficient radiation emission.

Further embodiments provide a quantum dot structure and a method to produce a quantum dot structure.

According to at least one embodiment, a quantum dot structure is specified, in particular a colloidal quantum dot structure. In particular, the quantum dot structure is configured or designed to absorb incident electromagnetic radiation of a first wavelength range, a primary radiation, convert the primary radiation into electromagnetic radiation of a second wavelength range, a secondary radiation, and emit the secondary radiation. In other words, the quantum dot structure may be or comprise a conversion material.

According to at least one embodiment, the quantum dot structure comprises a core comprising or consisting of a III-V-compound semiconductor material. In particular, a binary, ternary or quaternary material may be used. The core is arranged, for example, centrally, in the quantum dot structure. The core is enclosed in or surrounded by at least three regions or shells. For example, the core has a diameter of 2 nm inclusive to 10 nm inclusive.

Here and in the following, III-V-compound semiconductor materials are compound semiconductor materials comprising one or more chemical elements selected from the third main group of the periodic table, for example, indium and gallium as well as one or more chemical element selected from the fifth main group of the periodic table, for example, phosphorus. III-V-compound semiconductor materials, for example, comprise In, Ga phosphides. For instance, the light-emitting character of the quantum dot structure is determined by a III-V-compound semiconductor material.

According to at least one embodiment, the quantum dot structure comprises an intermediate region comprising or consisting of a III-V-compound semiconductor material at least partially, preferably completely, surrounding the core and the intermediate region. In particular, a binary, ternary or quaternary material may be used. The intermediate region, for example, has a thickness of 0.25 nm inclusive to 5 nm inclusive.

According to at least one embodiment, the quantum dot structure comprises a shell comprising or consisting of a III-V-compound semiconductor material at least partially, preferably completely, surrounding the core and the intermediate region. In particular, a binary, ternary or quaternary material may be used. The shell, for example, has a thickness of 2 nm inclusive to 20 nm inclusive.

According to at least one embodiment, the quantum dot structure comprises a passivation region comprising or consisting of a II-VI-compound semiconductor material at least partially, preferably completely, surrounding the shell. The passivation region is configured or designed for electronic passivation. The passivation region may further improve robustness and/or confinement. The passivation region may have a larger band gap than the core and/or the intermediate region and/or the shell. For example, the passivation region comprises or consists of ZnS or ZnSe, preferably ZnS. The passivation region, for example, has a thickness of 2 nm inclusive to 20 nm inclusive.

According to at least one embodiment, the quantum dot structure comprises a core comprising a III-V-compound semiconductor material, and intermediate region comprising a III-V-compound semiconductor material at least partially surrounding the core, a shell comprising a III-V-compound semiconductor material at least partially surrounding the core and the intermediate region, and a passivation region comprising a II-VI-compound semiconductor material at least partially surrounding the shell.

Here and in the following, two elements such as layers or regions or shells or a core surrounding one another can be in direct contact or the two elements can be spaced apart from each other.

In a further embodiment, the core is in direct contact to the intermediate region, the intermediate region is in direct contact to the shell and the shell is in direct contact to the passivation region.

According to at least one embodiment, the quantum dot structure comprises a light-emitting region. In particular, the light-emitting region is, for example, the core or the intermediate region. The light-emitting region is configured to emit radiation in the visible spectral range, for instance. For example, the light-emitting region is configured to emit radiation in the red, green or yellow spectral range.

The quantum dot structure may be provided as colloid or be transformed into powder or paste, for instance.

The term quantum dot structure broadly covers all structures where charge carriers experience a quantization of energy states due to confinement. In particular, the maximum extent of the light-emitting region is so small that quantization of energy states occurs. For instance, the maximum extent of the light-emitting region is between 1 nm and 15 nm. The light-emitting region inter alia may have an essentially circular or elliptical cross section.

In other words, the quantum confinement effect enables tuning of the emission wavelength of the quantum dot structure by the size of the nanocrystals, if the dimensions of the light-emitting nanocrystals from the semiconductor materials are smaller than the exciton Bohr radius of the corresponding bulk material.

Although the peak emission wavelength can be finely tuned by choosing the size of the dots, the smaller the nanocrystal, the greater its surface-to-volume ratio and the more difficult it may be to synthesize stable and efficient quantum dots. On the other hand, when the size of nanocrystal increases it is easier for crystalline imperfections to be formed and therefore endanger performance. In order to maintain the best performance and stability with an optimum structure of a relatively large nanocrystal, the emission wavelengths may be tuned not just by size, but by selection of semiconducting materials and/or by using their alloys. Further properties of the nanocrystals may be optimized by tuning the composition of the alloys at the interfaces, by applying structures with interlayers and staggered energy levels, and by using gradient multilayer shells with engineered lattice strain. Such quantum dot structures emitting in various wavelength ranges may exhibit high efficiency and stability. The composition and architecture can be further designed and optimized for energy level alignment of the cores and shells and for target Stokes' shift of the quantum dots.

According to at least one embodiment the quantum dot structure, in particular the light-emitting region, comprises a III-V-compound semiconductor material. Furthermore, a region directly adjoining the light-emitting region, for instance a barrier region or a shell region, may also comprise a III-V-compound semiconductor material.

Quantum dot structures comprising III-V-compound semiconductor materials allow for the generation of radiation in the visible spectral range. The use of Cd may be dispensed with, in particular for the light-emitting region. That is to say, according to at least one embodiment the light-emitting region is free of Cd.

According to at least one embodiment, the core and/or the intermediate region and/or the shell comprises In₁₋ₓGaₓP with 0≤x≤1. In other words, at least one of the following elements comprises In₁₋ₓGaₓP with 0≤x≤1: the core, the intermediate region, the shell. The parameter x is equal to or greater than 0 and smaller than or equal to 1. Here and in the following, the material system In₁₋ₓGaₓP is also referred to as InGaP. Thus, the term InGaP also includes GaP and InP. In particular, the light-emitting region comprises InGaP.

A quantum dot structure with a light-emitting region based on InP, for example, exhibits broader emission in the ensemble spectra than II-VI semiconductor materials because of a relatively large Bohr radius and stronger quantum confinement in nanocrystals of the desired size, in particular stronger than in Cd-containing quantum dots. Small variations in size may introduce noticeable inhomogeneous broadening of the photoluminescence on the ensemble level. If desired, this broadening may be minimized.

According to at least one embodiment, the core and/or the intermediate region and/or the shell comprises In₁₋ₓGaₓP with 0≤x≤0.63. In other words, at least one of the following elements comprises In₁₋ₓGaₓP with 0≤x≤0.63: the core, the intermediate region, the shell. In particular, the light-emitting region, for example, the core or the intermediate region, comprises or consists of In₁₋ₓGaₓP with 0≤x≤0.63. The parameter x is equal to or greater than o and smaller than or equal to 0.63. According to a further embodiment, the core and/or the intermediate region and/or the shell, in particular the light absorbing region, comprises In₁₋ₓGaₓP with 0≤x≤0.15. For x smaller than or equal to 0.63, In₁₋ₓGaₓP has a direct band gap. More efficient absorption and emission of radiation is facilitated compared to the compositions corresponding to the indirect gap.

For emission wavelengths smaller than 630 nm, the light emitting region, in particular the core or the intermediate region, can comprise or consist of compositions with x<0.63 in combination with quantum confinement to shift the emission further towards the blue. x=0.63 corresponds to the last direct bandgap before switching over to the indirect bandgap at x>0.63. x=0.63 corresponds to the approximate edge emission of 697 nm, and thus all shorter/emission wavelengths would occur in indirect bandgap under the “bulk” conditions with weaker, phonon-mediated transitions. The usefulness of In₁₋ₓGaₓP with x<0.63 for strong absorption in the absorbing regions of the quantum well structure, to capture the excitation by blue light, can be argued by means of quantum confinement the same way.

According to at least one embodiment, the intermediate region comprises a graded alloy of the III-V-compound semiconductor material of the core and the III-V-compound semiconductor material of the shell. The intermediate region may comprise all chemical elements present in the core and the shell. For example, the core comprises InP, the intermediate region comprises InGaP, and the shell comprises GaP. Alternatively, the core and/or the shell may comprise chemical elements not present in the intermediate region. For example, the core comprises InZnP, the intermediate region comprises InGaP, and the shell comprises GaP.

In particular, a lattice constant of the material of the intermediate region is between the lattice constants of the materials directly adjoining the intermediate region on opposite sides. Thus, the lattice constant of the intermediate region may be between the lattice constants of the materials of the core and the shell. For example, the lattice constant of the core is greater than the lattice constant of the intermediate region and the lattice constant of the shell is smaller than the lattice constant of the intermediate region or vice versa. An intermediate region comprising a graded alloy of the core and shell materials may facilitate lattice matching and thus reduce strain between the core and the shell.

According to at least one embodiment, the intermediate region and the shell comprises at least one chemical element not present in the core, and wherein the concentration of the chemical element in the intermediate region increased at least partially from core to shell. For example, the core comprises InP, the shell comprises GaP and the intermediate region comprises InGaP with an increasing concentration of Ga from core to shell. This further reduces strain due to lattice mismatch of the core and the shell.

According to at least one embodiment, the quantum dot structure comprises a core-shell structure or geometry. For instance, the core forms the light-emitting region and represents the innermost region of the quantum dot structure. The shell can be configured to absorb incident electromagnetic radiation, for example, primary radiation. The band gap of the intermediate region and/or shell may be larger or smaller, preferably larger, than the band gap of the core. In a core-shell geometry, the intermediate region can, in particular, be a graded alloy. Using a graded alloy for the intermediate region, a graded alloy core-shell structure may be obtained, for instance, a structure comprising InP/InGaP/GaP or related quaternary structures such as InZnP/InGaP/GaP which may be made by colloidal synthesis methods. A graded alloy core-shell structure can reduce strain due to lattice mismatch of the core and the shell.

The shell composition and thickness may be designed in view of the desired application. For photoluminescence efficiency a thick, bulky shell may be preferred, as such architecture ensures greater efficiency and non-blinking behavior. In electroluminescent (EL) applications the shell may have a smaller thickness for better performance. The thin shell may allow for more efficient charge extraction from the dots and greater efficiency of the electroluminescent devices. Thus, application specific requirements may be satisfied by an optimization of the composition and/or the thickness of the shell while maintaining their optical performance.

According to at least one embodiment, the core, the shell, and the intermediate region form a quantum well structure. A quantum well structure can also be referred to as a quantum dot quantum well (QDQW) structure or geometry. In this geometry, the light-emitting region is arranged between two barrier regions or absorbing regions, the absorbing regions having a larger band gap than the light-emitting region. In particular, the intermediate region is the light-emitting region and the core and the shell are the absorptive regions. For example, the core, the shell, and the intermediate region are all absorptive. Only the intermediate region is emissive. For instance, the light-emitting region completely surrounds the core and/or the shell region completely surrounds the light-emitting region. For example, the quantum dot quantum well structure includes GaP/InP/GaP or InGaP/InP/InGaP or analogous quaternary structures such as GaP/InZnP/GaP. These structures may be made by colloidal synthesis methods and the methods of synthesis of such QW structure.

According to at least one embodiment, the quantum dot structure has a symmetric or asymmetric shape. The quantum dot structure can be radially symmetrical, for example spherical. Alternatively, the quantum dot structure can be axisymmetric, for example, having a basic shape of a rod. In particular, a dot-in-rod structure may be used. Alternatively, the quantum dot structure can have a basic shape of a platelet or a tetrapod.

According to at least one embodiment, the quantum dot structure has an emission spectrum width of at most 50 nm or at most 30 nm or at most 20 nm or at most 15 nm. These values refer to the full width at half maximum (FWHM).

According to at least one embodiment, the core and/or the intermediate region and/or the shell is free of Cd. In particular, the light-emitting region of the quantum dot structure is free of Cd. This facilitates a broader use of the quantum dot structure, in particular compared to Cd containing quantum dots.

According to at least one embodiment, the III-V-compound semiconductor material of the core and/or the intermediate region and/or the shell comprises a minor component. For example, the minor component is a catalyst remaining in III-V-compound semiconductor material. In particular, the minor component may be less than 50 wt % (weight-%), less than 40 wt %, less than 30 wt %, in particular less than 20 wt %, preferably less than 10-15 wt % of the III-V-compound semiconductor material of the core and/or the intermediate region and/or the shell. It should be noted that despite the minor component, the light-emitting character of the quantum dot structure is determined by the III-V-compound semiconductor materials. The minor component may be a chemical element, in particular a metal, for example Zn. According to at least one embodiment, the core and/or the intermediate region and/or the shell comprises Zn. Thus, quaternary quantum dot structures such as GaP/InZnP/GaP or InZnP/InGaP/GaP can be formed.

According to at least one embodiment, the intermediate region comprises a smaller bandgap than the core and the shell. For example, the intermediate region comprises a smaller bandgap than the core and the shell in a GaP/InP/GaP structure or a GaP/InGaP/GaP structure or a InGaP/InP/InGaP structure. In particular, a smaller bandgap in the intermediate region than in the core and the shell leads to the formation of a quantum well structure.

According to at least one embodiment, the quantum dot structure comprises an intermediate passivation region comprising a II-VI-compound semiconductor material between the shell and the passivation region. In other words, the passivation region comprises two layers or regions to facilitate lattice matching between the shell and the passivation region as well as to improve carrier confinement and electronic passivation. The intermediate passivation region can comprise or consist of the same or a different material than the passivation region.

In particular, disclosed herein are multi-layer quantum dot quantum wells (QDQWs) including GaP/InP/GaP and GaP/InGaP/GaP structures as well as InGaP/InP/InGaP structures with proper composition, which may further be overcoated with larger bandgap materials (including II-VI compounds such as ZnS and ZnSe and their alloys) and/or further layers for further robustness. “Proper composition” in conjunction with a InGaP/InP/InGaP structure means that the core and the shell comprising InGaP are configured to absorb radiation and the intermediate region comprising InP is configured to emit radiation. These structures may be made by colloidal methods, which are disclosed below.

The disclosed designs of the nanocrystals, in particular of the multi-layer core-shell nanocrystals, may include material arrangements selected with consideration of their crystallographic structures, lattice parameters and/or their electronic properties such as the band gap Eg, absorption, and the position and alignment of valence (VB) and conduction (CB) bands, which all together can enable carrier confinement in the inner parts of the quantum dot structure, for instance in the light-emitting region, and by such enable efficient radiative recombination.

Other embodiments relate to a light-emitting device. Preferably, the light-emitting device described here comprises a plurality of quantum dot structures described above. Features and embodiments of the quantum dot structure are also disclosed for the light-emitting device and vice versa. The quantum dot structure may have one or more features disclosed above or in connection with the exemplary embodiments.

The light-emitting device is a device configured or designed to emit electromagnetic radiation during operation. For example, the light-emitting device is a light-emitting diode (LED).

According to at least one embodiment, the light-emitting device comprises a semiconductor chip configured to emit primary radiation during operation and a conversion element comprising a plurality of quantum dot structures, wherein the quantum dot structures are configured to convert at least part of the primary radiation into secondary radiation during operation.

The semiconductor chip can comprise an active layer stack comprising an active region that emits primary radiation during operation of the device. The semiconductor chip is, for example, a light-emitting diode chip or a laser diode chip. The primary radiation generated in the semiconductor chip can be emitted through a radiation emission surface of the semiconductor chip. In particular, the semiconductor chip emits a primary radiation in the UV or visible wavelength range during operation, for example, in the blue wavelength range.

The quantum dot structures in the conversion element are configured to convert the primary radiation at least partially or completely into a secondary radiation. In particular, the secondary radiation has a wavelength range that is at least partially, preferably completely, different from the wavelength range of the primary radiation. In particular, a wavelength of maximum intensity of the secondary radiation is larger than a wavelength of maximum intensity of the primary radiation. In other words, the quantum dot structure acts as a downconverter. This allows creating colored or white light, for instance. Preferably, the wavelength range of the secondary radiation is in the visible wavelength range.

The features of the quantum dot structure have already been disclosed in conjunction with the quantum dot structure and also apply to the quantum dot structures in light-emitting device.

Such a light-emitting device can be used for emitting white light or colored light using quantum dot structures comprising III-V-compound semiconductor materials as down converting materials.

According to at least one embodiment, some of the quantum dot structures are arranged in direct contact to the semiconductor chip. Thus, the conversion element is arranged in direct contact to the semiconductor chip. In other words, the quantum dot structures are arranged near-chip or on-chip.

Yet other embodiments relate to a method of producing a quantum dot structure. Preferably, the method described here is used to produce the quantum dot structures described above. Features disclosed in connection with the quantum dot structure and/or the light-emitting device are therefore also disclosed for the method and vice versa.

According to at least one embodiment, the method comprises:

forming a core comprising a III-V-compound semiconductor material,

forming an intermediate region comprising a III-V-compound semiconductor materials at least partially surrounding the core,

forming a shell comprising a III-V-components semiconductor material at least partially surrounding the core and the intermediate region.

With such a method, quantum dot structures comprising III-V-compound semiconductor materials can be produced allowing for the generation of radiation in the visible spectral range without using Cd-containing materials.

According to at least one embodiment, forming the core comprises a cationic exchange process. The cationic exchange process may be performed multiple times and create nanoparticles with desired crystallographic structures.

According to at least one embodiment, forming the core comprises converting a wurtzite phosphide material into wurtzite InGaP, GaP or InZnGaP. For instance, a hexagonal template is used. For instance, if InP or InZnP is used, this may be obtained using total or partial cation exchange with an appropriate Ga precursor. Wurtzite InGaP may result in more strongly absorbing nanoparticles compared to zinc blende analogs.

According to at least one embodiment, forming the core comprises converting a cubic InGaP, GaP or InZnGaP into hexagonal InGaP, GaP or InZnGaP by a crystal phase change. In particular, this conversion may be performed post-synthesis. This can be done using a so-called “digestive ripening” method.

According to at least one embodiment, forming the core comprises using an aminophosphine precursor. It has been found that these precursors are particularly suited for the formation of InGaP.

According to at least one embodiment, forming the core comprises producing InGaP nanocrystals, GaP nanocrystals or InZnGaP nanocrystals by using a reduction of an aminogallane precursor. The reduction step produces a grey precipitate that reacts, for instance, with dimethylaminophosphine, phosphorus trichloride, or tris(trimethylsilyl)phosphine in amine solution. Depending on the structure of the dialkylamine or the presence of n-alkylamines, the particle size can be tuned.

According to at least one embodiment, the method further comprises forming a passivation region comprising a II-VI-compound semiconductor material at least partially surrounding the shell. For example, the passivation region comprises or consists of ZnS or ZnSe.

According to at least one embodiment the method further comprises forming a intermediate passivation region comprising a II-VI-compound semiconductor material at least partially surrounding the passivation region. For example, intermediate passivation region comprises or consists of the same or a different material than the passivation region.

It has been found that at least one or more of the above described features of the method results in an efficient synthesis of non-Cd containing quantum dot structures from III-V-compound semiconductor material even though the synthesis is more challenging due to the reactivity of the most successful reagents and toxicity of some reagents and reaction byproducts.

According to at least one embodiment, the quantum dot structure comprises a light-emitting region, wherein the light-emitting region comprises a III-V-compound semiconductor material.

According to at least one embodiment, the light-emitting region comprises In₁₋ₓGaₓP with 0≤x≤1.

According to at least one embodiment, the light-emitting region comprises In₁₋ₓGaₓP with 0≤x≤0.63.

According to at least one embodiment, the light-emitting region is free of Cd.

According to at least one embodiment, the quantum dot structure comprises a core-shell geometry.

According to at least one embodiment, the quantum dot structure comprises a quantum dot quantum well geometry.

According to at least one embodiment, the quantum dot structure comprises a passivation region including a II-VI-compound semiconductor material.

According to at least one embodiment, the quantum dot structure comprises a protective region.

According to at least one embodiment, the light-emitting device comprises a quantum dot structure comprising a light-emitting region, wherein the light-emitting region comprises a III-V-compound semiconductor material.

According to at least one embodiment the light-emitting device comprises a semiconductor chip, wherein the semiconductor chip is configured to emit primary radiation during operation, and wherein the quantum dot structure is configured to convert at least part of the primary radiation into secondary radiation during operation.

According to at least one embodiment, the method of producing a quantum dot structure comprises forming a light-emitting region comprising a III-V-compound semiconductor material.

According to at least one embodiment, the method further comprises a cationic exchange process.

According to at least one embodiment, the method further comprises converting a wurtzite material into InGaP.

According to at least one embodiment, the method further comprises converting cubic InGaP into hexagonal InGaP by a crystal phase change.

According to at least one embodiment, the method further comprises using an aminophosphine precursor.

According to at least one embodiment, the method further comprises producing InGaP by using a reduction of an aminogallane precursor.

### BRIEF DESCRIPTION OF THE DRAWINGS

Further conveniences and developments of the quantum dot structure, the light-emitting device and the method will become apparent from the exemplary embodiments described below in association with the figures.

In the Figures:

FIG. 1A shows an exemplary embodiment of a quantum dot structure in a sectional view;

FIG. 1B shows a band gap diagram of the quantum dot structure of FIG. 1A;

FIG. 2A shows absorption and emission spectra of an InP/ZnSe/ZnS structure;

FIG. 2B shows absorption and emission spectra of a GaP/InP/GaP quantum dot structure;

FIG. 3 shows a table listing various parameters for InP. GaP, ZnSe and ZnS semiconductor compound material;

FIG. 4A shows an exemplary embodiment of a quantum dot structure in a sectional view;

FIG. 4B shows an exemplary embodiment of a quantum dot structure in a sectional view;

FIG. 5 shows the lattice constant a, the band gap energy Eg and the corresponding wavelength for InₓGa₁₋ₓP;

FIG. 6 shows an exemplary embodiment of a quantum dot structure in a sectional view;

FIGS. 7A, 7B, 7C, 7D, 7E, 7F, 7G, 7H, 7I, 7J, 7K, and 7L show exemplary embodiments of a quantum dot structure in sectional views;

FIG. 8A shows a representation of a strain distribution of a GaP inclusion in InP;

FIG. 8B shows a representation of a strain distribution of a InP inclusion in GaP;

FIG. 8C shows a representation of a strain distribution of a GaP inclusion in In_{0.37}Ga_{0.63}P;

FIG. 8D shows a representation of a strain distribution of an In_{0.37}Ga_{0.63}P inclusion in GaP;

FIGS. 9A, 9B and 9C show diagrams of a band alignment in GaP/InP/GaP spherical nanocrystals approximately calculated without considerations for quantum confinement (FIG. 9A), with quantum confinement in InP (FIG. 9B, for the red 625 nm and green 525 nm quantum dot emission wavelengths) and with quantum confinement in InP and in GaP (FIG. 9C, same emission wavelengths);

FIG. 10 shows a trend in energy band gap of GaP and InP as a function of temperature;

FIG. 11A shows a schematic representation of a pseudomorphic and a partially relaxed layer;

FIG. 11B shows an illustration of a critical thickness he of an epitaxial layer as a function of the strain;

FIG. 12A shows a schematic representation illustrating a model to estimate strain according to Timoshenko and Goodier, Theory of elasticity, 2004;

FIG. 12B shows a simulation of maximum tangential strain □ₜ as a function of b/a;

FIG. 13 shows a simulation of tangential tension as a function of b/a;

FIG. 14 shows results from X-ray diffraction and Raman spectrum measurements of GaP quantum dots;

FIG. 15 shows an exemplary embodiment of a method of producing a quantum dot structure;

FIG. 16 shows an exemplary embodiment of a method of producing a quantum dot structure;

FIG. 17A shows a TEM image of GaP particles produced by a Redox method;

FIG. 17B shows a TEM image of GaP particles produced by a cation exchange method;

FIG. 18 shows an exemplary embodiment of a light-emitting device with a quantum dot structure; and

FIGS. 19 and 20 each show an exemplary embodiment of a quantum dot structure in a sectional view.

In the exemplary embodiments and figures, similar or similarly acting constituent parts are provided with the same reference symbols. The elements illustrated in the figures and their size relationships among one another should not be regarded as true to scale [unless otherwise indicated]. Rather, individual elements may be represented with an exaggerated size for the sake of better representability and/or for the sake of better understanding.

### DETAILED DESCRIPTION OF ILLUSTRATIVE EMBODIMENTS

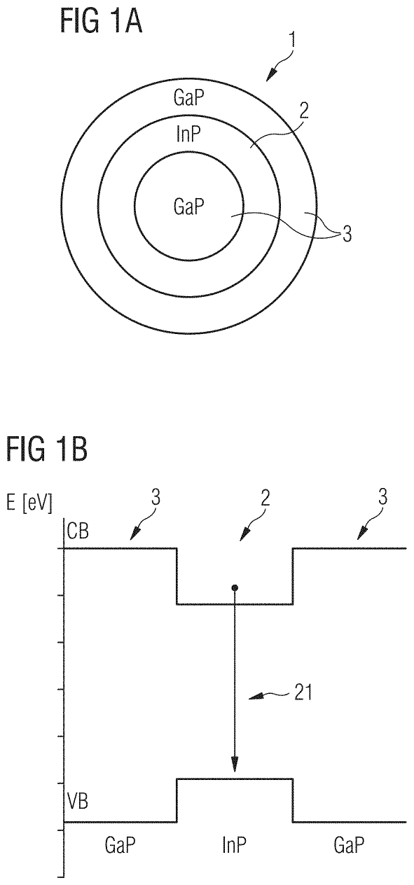

An exemplary embodiment of a quantum dot structure with a quantum well geometry is shown schematically in FIG. 1A, wherein FIG. 1B illustrates the associated band structure.

The quantum dot structure 1 is based on the InP/GaP material system. A light-emitting region 2 is formed by InP. The light-emitting region is arranged between two barrier regions 3 of GaP. In particular, the light-emitting region 2 is free of Cd. Thus, the above structure represents a GaP/InP/GaP quantum well (QW) structure forming a colloidal quantum dot system. The quantum dot structure 1 can comprise further layers or regions such as a passivation region comprising a II-VI-compound semiconductor material at least partially surrounding the outer barrier layer 3.

GaP serves as an absorber of shorter wavelength primary exciting radiation (blue, for example) while the InP serves as the emitter of secondary, converted radiation). Both semiconductors crystalize in zinc blende (ZB) structure. Bulk GaP has a room temperature (RT) bandgap of 2.27 eV while InP has a bandgap of 1.35 eV at RT (300K), and the offset between the valence and conduction bands between the two is such that the structures will be type 1, as illustrated in FIG. 1B. Consequently, both electrons and holes are confined within the light-emitting region 2.

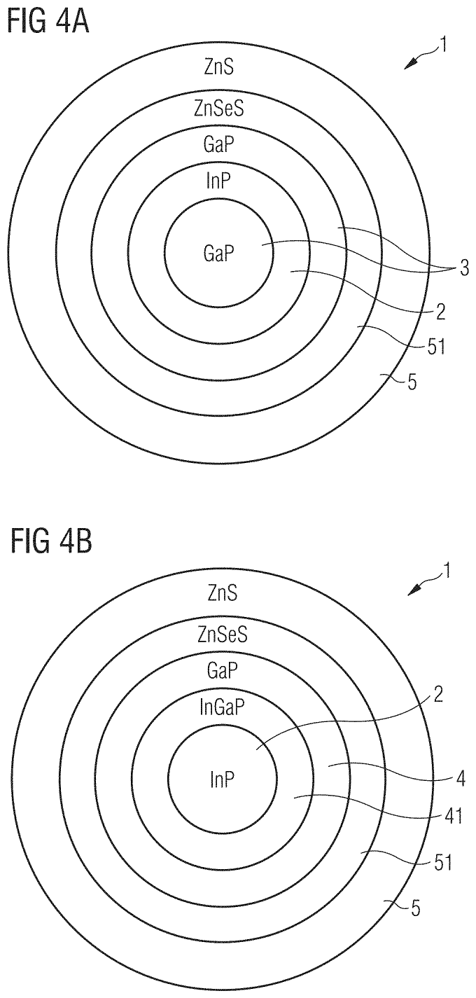

Although there is a somewhat significant lattice mismatch of about 8% between the GaP (cubic lattice constant 5.45 Å)and InP (cubic lattice constant 5.87 Å), a properly designed quantum well configuration will allow to reduce the strain. GaP has a smaller lattice mismatch with ZnS (a=5.41 Å), which is a candidate for a material for the passivation region as well as ZnSe (a=5.67 Å). A quantum dot structure with a passivation region will be described in detail in connection with FIGS. 4A and 4B.

In non-QW core/shell variants with a core-shell geometry, In—Ga graded alloying will be utilized to minimize the detrimental impact of interfacial strain. A core-shell architecture is shown in FIG. 4B, for instance. Zn may be exchanged for either In or Ga in each layer, providing an additional opportunity for lattice and bandgap engineering. For example, InZnP is predicted to have a lattice spacing comparable to ZnS at a Zn:In ratio of approximately 3.5.

The light-emitting layer 2 and/or the barrier region 3 may also comprise In₁₋ₓGaₓP, wherein the Ga content x of the light-emitting layer 2 is determined specifically for the core-shell structure or the quantum well structure of the quantum dot structure 1.

Lattice parity can be attained for InGaP which may be preferred, in particular with respect to the lattice constants in the hybrid structure in FIG. 1A. Furthermore, InGaP may be more highly absorbing at relevant blue LED wavelengths (e.g., 450 nm) than pure GaP.

For additional performance and protection, the outer semiconductor layer may optionally be coated with a further layer. The GaP/InP/GaP structures with additional further layers have a significant advantage in absorption and stability over InP quantum dots shelled by only ZnSe and ZnS.

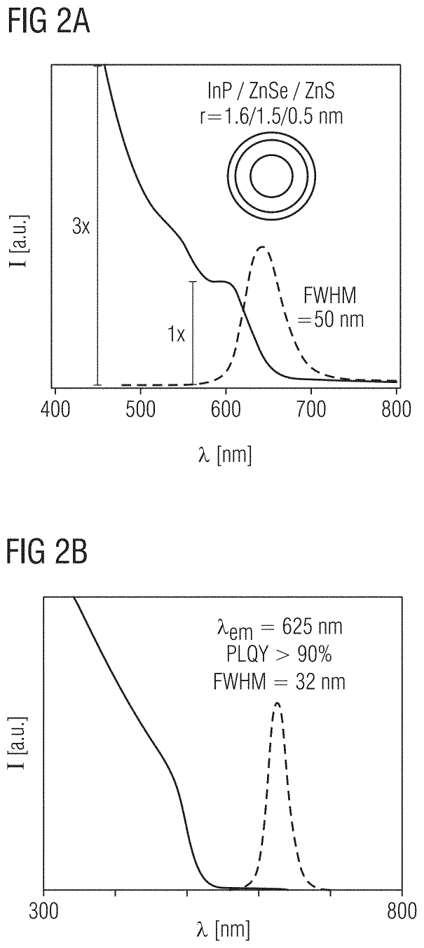

FIG. 2A and 2B show absorption and emission spectra. The intensity I in arbitrary units (a.u.) is plotted against the wavelength X in nm. The quantum dot structure 1 using a quantum well design may have a comparably small overlap or, in other words, a larger gap between absorption and emission spectra as illustrated in FIG. 2B as the absorption is dominated by GaP. In contrast, an InP/ZnSe/ZnS core-shell quantum dot structure will exhibit overlap between absorption and emission spectra, as shown in FIG. 2A, because absorption as well as emission predominantly takes place in the InP core.

Inclusion of a GaP layer as barrier region either atop or both beneath and atop the emissive InP layer provides the opportunity to independently enhance the UV and blue light absorption capacity of the composite material while maintaining a chosen emission color.

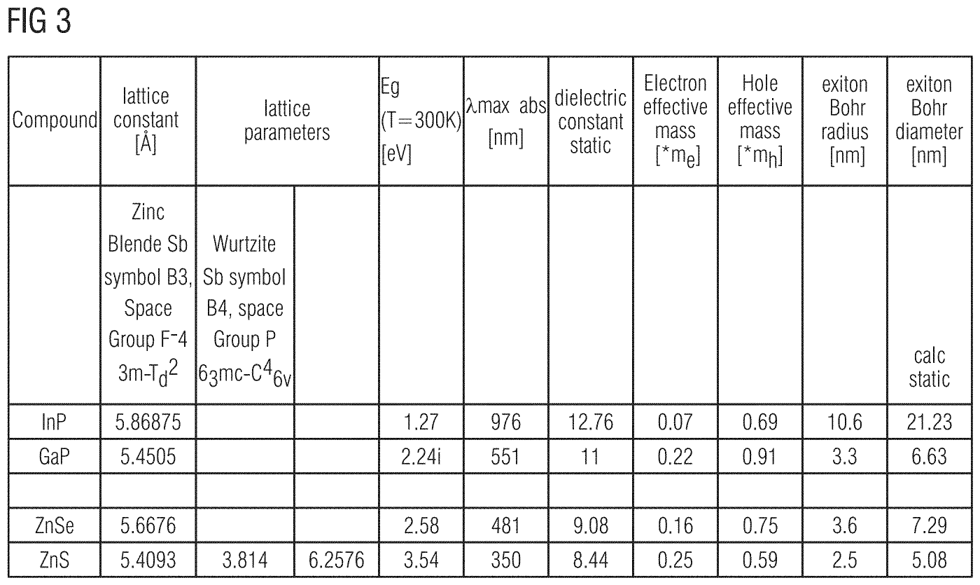

In addition to the choice of the quantum dot configuration, in particular quantum well design or core-shell design, the quantum dot structure may be appropriately designed using suitable materials to ensure a high degree of epitaxy between and within the III-V-compound semiconductor material and II-VI-compound semiconductor materials. FIG. 3 shows basic parameters of luminescent III-V-compound semiconductors InP and GaP and II-VI-compound semiconductors ZnSe and ZnS, which may be used for the quantum dot structure.

The quantum dot structure 1 illustrated in FIG. 4A essentially corresponds to that of FIG. 1A. In addition, the quantum dot structure comprises a passivation region 5 and an intermediate passivation region 51 between the passivation region and the outermost barrier region 3. The intermediate passivation region may reduce the strain between the passivation region 5 and the outermost barrier region 3. For instance, the intermediate passivation region 51 comprises ZnSeS. ZnSeS alloyed layers can smooth the strain between ZnSe and ZnS regions just as ZnSe_{0.16}S_{0.84} compound can match the lattice constant of GaP extending strain-free region of the nanocrystal.

FIG. 4B illustrates a core-shell quantum dot with an intermediate region 41 between the light-emitting region 2 representing the core and the shell 4. The passivation region 5 and the intermediate passivation region 51 may be configured as described in connection with FIG. 4A.

For instance InGaP may act as an intermediate between InP and GaP. In such a case, however, additional considerations for the impact of increasing concentration of Ga on the type of the bandgap and emissive properties of the resultant compound should be made.

FIG. 5 illustrates the trade-offs for bulk In₁₋ₓGaₓP alloys of various compositions at RT. Alloys with Ga concentration 0<x<0.63 exhibit a direct bandgap in the range of 1.35-1.78 eV. The corresponding absorption edge is between 697-919 nm and in this regime strong luminescence may be obtained. Alloys with Ga concentration greater than 63% exhibit an indirect bandgap, which leads to weaker band-to band transitions. The lattice constant of InP is larger than the one of GaP and lattice mismatch between the binary compounds (InP, GaP) and direct bandgap In₁₋ₓGaₓP alloys will be in the range from 2.8% to 7.7%. These properties need to be taken into consideration in designing low-dimensional structures.

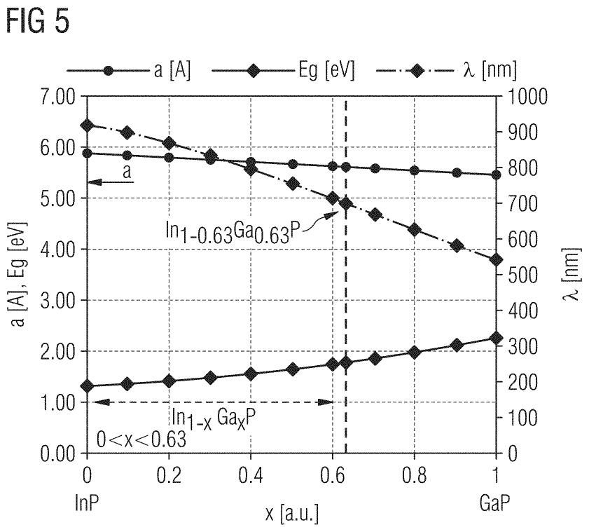

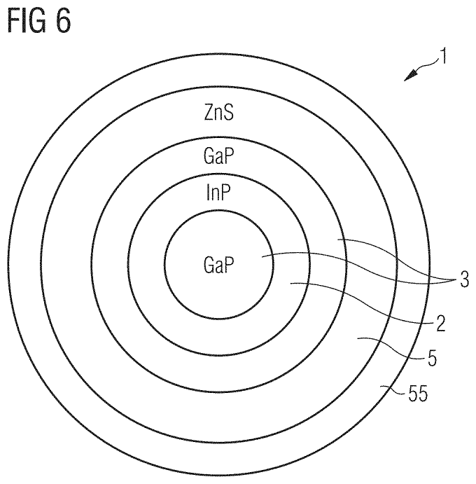

In the exemplary embodiment of FIG. 6, the quantum dot structure 1 comprises a further layer 55. The further region may be present in addition to the passivation region 5 or instead of the passivation region.

Thus, the passivation region 5 may comprise Cd. The Cd concentration of the quantum dot structure, however, is low compared to a quantum dot structure using Cd designated for the light-emitting or absorbing regions. In other words the quantum dot structure is Cd-depleted.

While the above figures depict particles as spherical or spheroidal, it should be understood that this is only for convenience of depicting the quantum dot structure in figures. In many cases it is advantageous to synthesize non-spheroidal, and even non-centrosymmetric morphologies such as “sphere-in-rod” geometries.

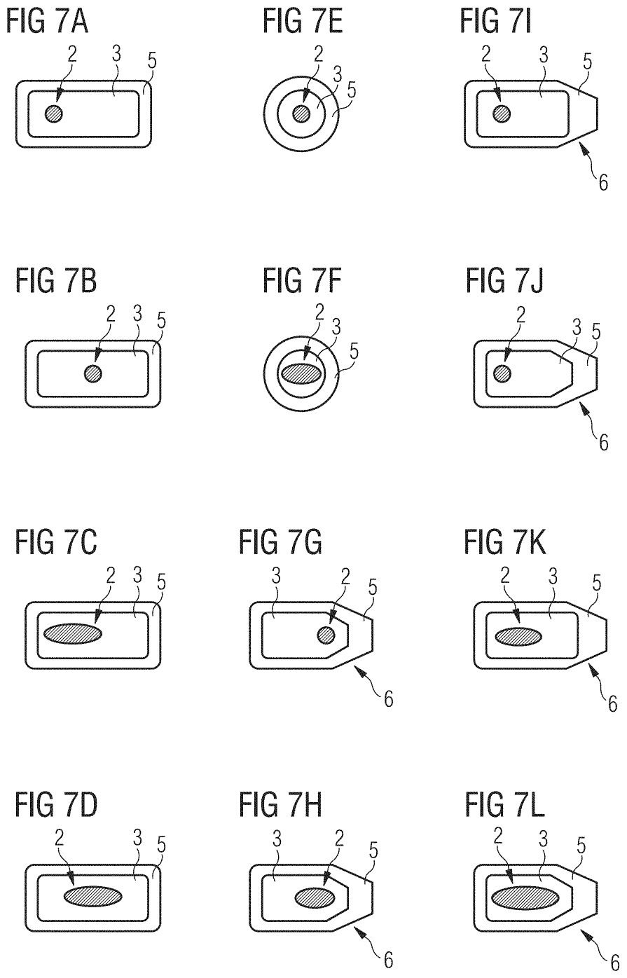

FIGS. 7A through 7L illustrate various examples for geometries that may apply. According to FIGS. 7A, 7B, 7C, 7D, 7G, 7H, 7I, 7J, 7K, and 7L the barrier region 3 corresponds to the shell as a rod-like structure. In sectional view, the rods may have a tapered region 6 as shown in FIGS. 7G, 7H, 7I, 7J, 7K, and 7L.

According to FIGS. 7E and 7F the particles are spherical.

The light-emitting region 2 representing the core may have a circular cross-section as shown in FIGS. 7A, 7B, 7E, 7G, 7I, 7J or elliptical cross-section as shown in FIGS. 7C, 7D, 7F, and 7H.

For example, the quantum dot structure may be an elongated rod-like GaP layer around either a spherical InP or a spherical GaP/InP seed. In this case the extra GaP material would provide an even higher degree of light absorption capacity while attenuating the otherwise large impact on GaP band energies and consequent alignment with InP bands. Other considerations such as cost and ease of synthesis might make non-spherical, especially rod-like, morphologies preferable in the seed or other outer layers. Such nanostructures can be created from pre-formed templates by methods of cationic exchange. The archetypes depicted in FIG. 7 represent some but not all of the geometries that may be useful in customizing the properties of the described quantum dot structure.

Additional embodiments provide the possibility of overcoming the well-known difficultly in generating InP-based quantum dot emission with narrow line widths (as compared to II-VI) analogs. As described above, the inferior line width is a result of electronic factors such as the large exciton Bohr radius of InP and stronger quantum confinement than in Cd-based counterparts. It was found that asymmetric compression of the luminophore in composite quantum dots via application of a material with a smaller lattice constant can result in significantly more narrow emission. The quantum well structures proposed here provide an ideal vehicle since compression of the InP lattice can be affected from both inside and outside the InP layer by the layers arranged beneath and above the InP layer.

Non-spherical morphologies as described above may augment this effect by allowing for differential surface reorganization along different axes.

Further embodiments provide the possibility of overcoming the well-known difficultly in generating InP-based quantum dot emission with narrow line widths (as compared to II-VI) analogs. As described above, the inferior line width is a result of electronic factors such as the large exciton Bohr radius of InP and stronger quantum confinement than in Cd-based counterparts. As for CdSe/CdZnS nanocrystals, it was found that asymmetric compression of the luminophore in composite quantum dots via application of a material with a smaller lattice constant can result in a significantly more narrow emission. The QW structures proposed here provide an ideal vehicle since compression of the InP lattice can be affected from both inside and outside the InP layer. Non-spherical morphologies as described above could augment this effect by allowing for differential surface reorganization along different axes (e.g., different terminal atom-to-atom bonding along the “flat” and “rounded” portions of the particles to compensate for dangling bonds).

Furthermore, the preferred growth axis which facilitates preparation of elongated particles provides an opportunity to enrich the lattice in dopants in certain dimensions using kinetic biases.

As mentioned above, there is a relatively large lattice mismatch between InP and GaP (up to 7.7%) and strain effects need to be taken into consideration in any multilayer structure based on these compounds. Strain in the lattice affects structural quality and electronic and optical properties of semiconductors. Magnitude and distribution of strain in nanocrystal can be assessed by using an approach from the classical theory of elasticity. In a first order approach it is helpful to analyze strain induced by single spherical inclusion embedded in the infinite matrix (host material) of smaller or larger lattice constant.

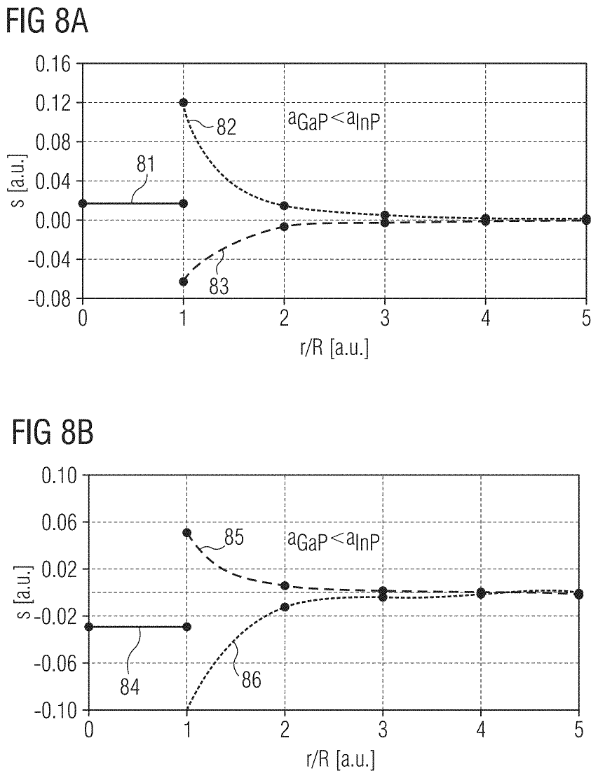

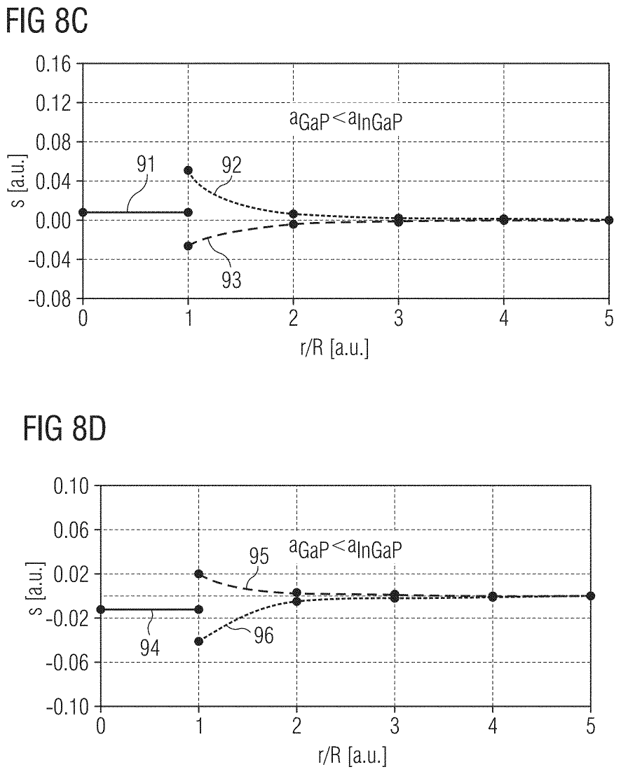

FIGS. 8A through 8D illustrate such considerations for strain distribution in inclusion/matrix configurations of an GaP inclusion in InP (FIG. 8A) and InP inclusion in GaP (FIG. 8B) and the like for GaP inclusion in In_{0.37}Ga_{0.63}P (FIG. 8C) and In_{0.37}Ga_{0. 63}P inclusion in GaP compositions (FIG. 8D). Curves 81 and 91 show the GaP inclusion. Curves 84 and 94 show the InP inclusion.

Strain components (s) in arbitrary units (a.u.) are plotted against the distance from the center of the inclusion (r) normalized to the radius of the inclusion (R) r/R in arbitrary units (a.u.). While inside the inclusion there is only hydrostatic strain of a constant value determined by the properties of the two materials involved, at the interface and further away its radial (er) and tangential (εt) components exhibit an (r/R)3 dependence.

Curves 83, 85, 93, 95 represent the tangential components et, wherein curves 82, 86, 92 and 96 represent the radial components er.

Maximum strain occurs at the interface of the inclusion and the matrix. The larger the lattice mismatch, the larger the resultant strain at the interface. Thus, to reduce strain at the interface a ternary alloy may be used as one of the materials. As an example, by replacing the InP or GaP inclusion in the respective matrix materials with an In 0.37 Ga 0.63P composition, radial and tangential strain at the interface of the two materials can be reduced nearly 3 times while a direct bandgap of the InGaP emissive layer is still maintained for maximum absorption strength of the direct bandgap material.

Band alignment of spherical inclusion of one semiconductor material embedded in the matrix of another semiconductor material can be visualized by using model-solid theory approach and considering strain distribution specific to the examined kind of structure. Starting from the position of the valence band obtained from ab-initio density functional theory (DFT)calculations for individual bulk semiconductors found in the databases and literature, further energy levels in the heterostructures can be found by analytical calculations.

Since DFT does typically not accurately predict the energy bandgap Eg, experimental values of Eg are being used to determine the position of the conduction band in these considerations. Then, spin-orbit splitting for the valence band and further energy shifts due to the strain induced by lattice mismatch may be added.

For assessing the band offsets in GaP/InP/GaP spherical nanocrystal as shown in FIG. 1A, the above approach was applied to the GaP inclusion in InP matrix and to the reversed configuration of semiconductors, i.e., InP inclusion in GaP matrix.

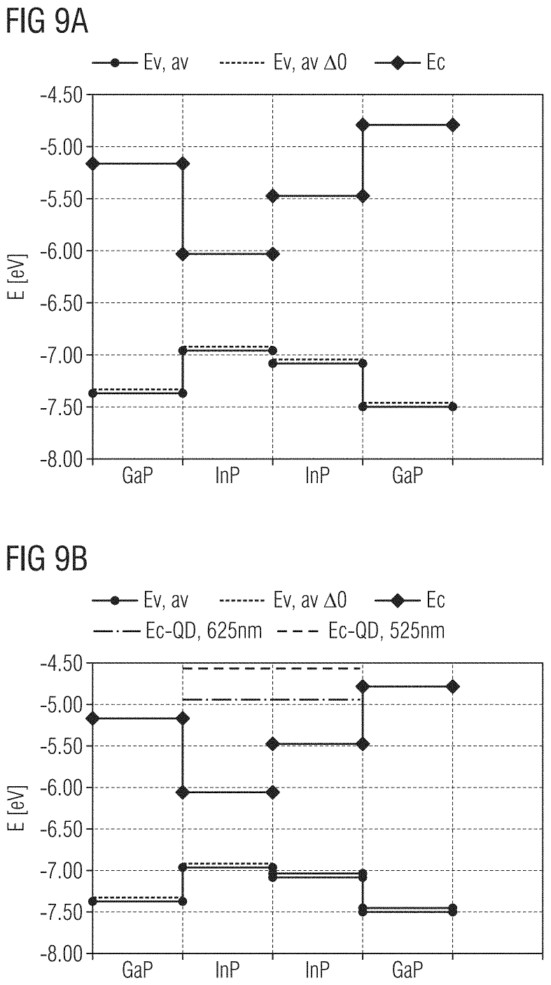

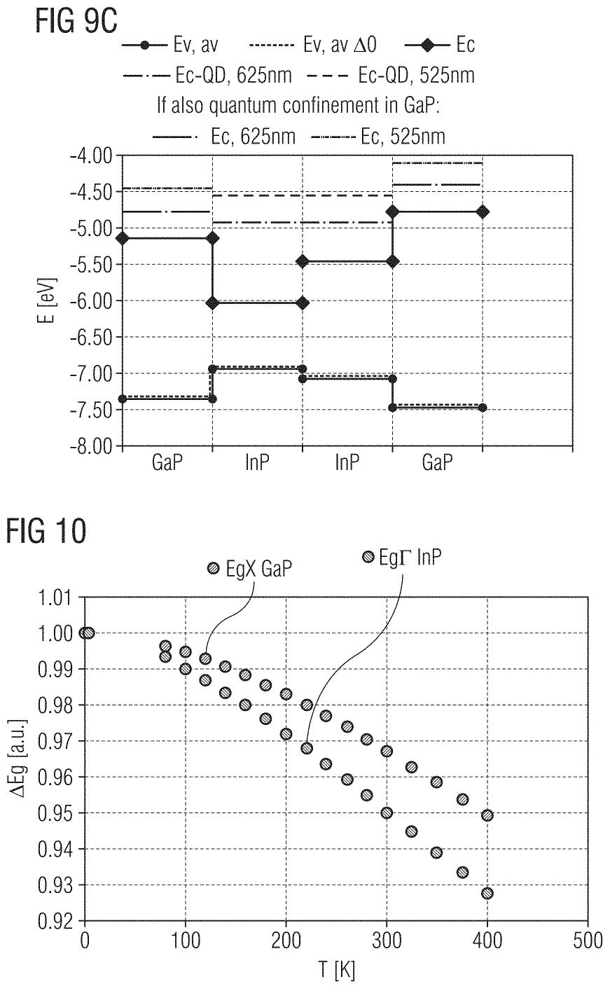

FIG. 9A shows the band diagram of GaP/InP/GaP without considerations for quantum confinement. The discontinuity within the inner InP layer (double values) originates from the fact that the InP/GaP band alignment is calculated for InP inclusion in GaP, not for the GaP/InP particle in GaP. This represents a good first order approach. As shown in FIG. 9A both carriers, electrons and holes, are confined within the inner InP layers.

If quantum confinement is considered in the InP layer, the band positions change. It is commonly accepted in the literature that quantum confinement shifts mainly the position of the conduction band and the valence band position varies little or is just assumed to remain unchanged. As such, FIG. 9B shows the band diagram for the GaP/InP/GaP nanocrystal emitting red 625 nm light or green 525 nm light. At this point, the shift of the conduction band corresponding to the emission of green light is large and type II band alignment is observed. For red emission the quasi type-I band alignment may be possible with a stronger confinement of the holes and delocalized electrons, according to the result of this estimate.

Of course, the results of the theoretical predictions have a certain error. The heterojunction band offsets derived by the model-solid theory for bulk and epitaxial layer correlate with the experimental data within 0.2-1 eV. Within this error, the quasi-type I band alignment for red emission quantum dot quantum well structures may be obtained.

The above calculations were made using literature data for low temperatures, as recommended by the theory. Consistent values for low temperature quantities can be found in databases and in the literature and this promises better accuracy of the predictions. For higher temperatures possible trends can be estimated by considering thermal dependencies of the band gaps. Although the differences for that in InP and GaP are only within a few percent, the energy band gap ΔE_{g} of GaP shrinks at a slower pace with increasing temperature than that of InP (FIG. 10). It is a favorable trend for the GaP/InP/GaP quantum dot quantum well to allow for even better band alignment at higher temperatures than predicted in FIGS. 9A and 9B.

Furthermore, for GaP and/or InGaP cores smaller than their respective exciton Bohr radius the energy level of the conduction band can also be raised. The similar effect may be induced in shell, as illustrated in FIG. 9C.

From FIGS. 8 and 9, it can be noticed that both strain and quantum confinement shift the conduction bands of the nanostructure upwards, increasing the risk of transforming the alignment of the conduction bands to type II (staggered conduction and valence bands). Thus, the impact of strain may be reduced by using an InGaP alloy with the composition from the range of the direct band gap instead of pure InP. In such a situation the InGaP would form the light-emitting region emissive medium under the constraint of Ga concentration in the alloy lower than 63%. (FIG. 5).

Furthermore, an InGaP alloy may be employed as an absorbing medium (barrier layer) instead of pure GaP. In such a case the band gap of the InGaP would have to be greater than the band gap of the light-emitting region. In consideration of red-emitting quantum dot quantum well nanostructure, Eg of the absorbing alloy would have to be greater than ˜2.05 eV (605 nm), which would impose the limit of no more than 15% of InP in the alloy of InGaP under the bulk and zero temperature conditions. These values are expected to adjust themselves somewhat to the quantum confinement regime.

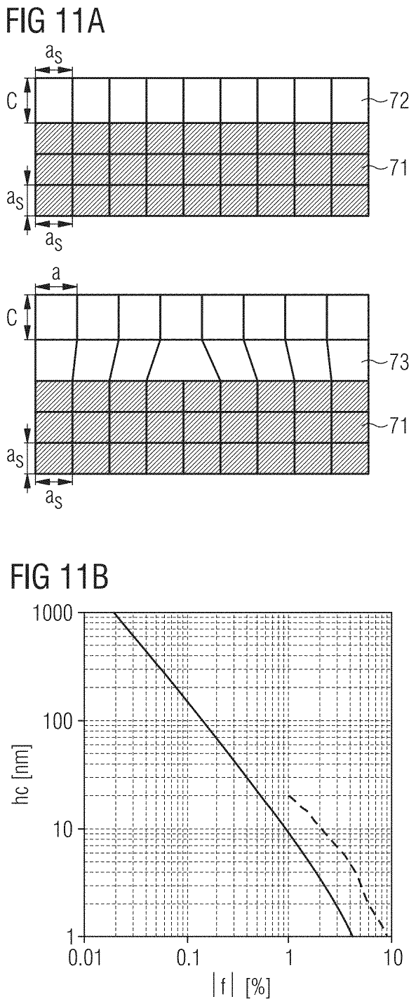

Further, consideration may be given to the crystalline quality of the light-emitting region. In nanocrystals, similarly to the epitaxial films, strain in the lattice and critical thickness for dislocations-free materials are inter-related. Critical thickness (of epitaxial layer) is defined as the maximum thickness of the strained layer without dislocations. Predictions by theoretical calculations underestimate the critical thickness of a dislocation-free epi-layer by a factor of ˜2 compared to the experimental results. The dashed curve in FIG. 11B illustrates the discrepancy between the theory (solid line) and experiment for the critical thickness h_{c} as a function of the absolute value of the strain f in %.

Following these criteria and implications of experimental verification of the theory, the thickness of the QW emissive layer cannot exceed 2-3 nm for 6-7% lattice strain. However, it can be ˜5-6 nm when strain is reduced to 3%. FIG. 11A shows the illustration of such effects in epitaxial films resulting in a pseudomorphic layer 72 or a partially relaxed layer 73 on a substrate 71, for instance.

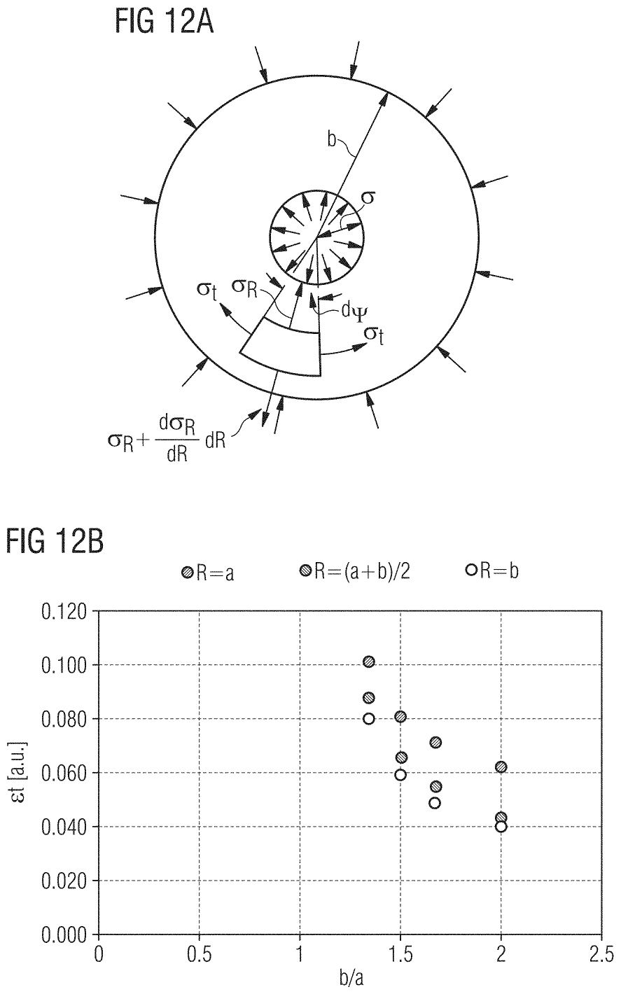

Architecture of the nanocrystal with respect to strain can be optimized even further, as shown in the example in FIG. 12B. Considering only hydrostatic strain in the inclusion originating from the lattice mismatch, it is possible to estimate preferred geometrical parameters. For the GaP/InP/GaP structure (FIG. 1A), the maximum tangential strain is estimated to be at the inner interface of GaP/InP (R=a in FIG. 12B) and it is decreasing when the thickness of the InP emissive layer is increasing. The upper limit for the thickness of the latter layer is imposed by the critical thickness of dislocation-free layer, i.e., 2-3 nm for 6-7% strain (GaP/InP/GaP case) or 5-6 nm for ₃% strain (GaP/InGaP/GaP case). This means that the preferred size of the “seed (core)” GaP or InGaP nanocrystal can be set for 4-6 nm and 10-12 nm range for these two options respectively.

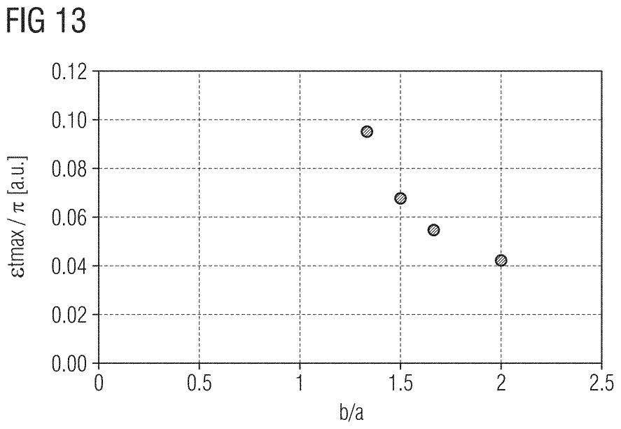

Further, a quantum dot quantum well structure, such as GaP/InP/GaP for instance, with external layers is considered. These external layers (passivation region) may improve chemical and environmental robustness. For instance, the quantum dot structure may include GaP/InP/GaP/ZnSeS, optionally with a further layer. Here again the issue of minimizing stress specifically at optically active layers of such a much more complex particle is important. Tangential tension of the particle from FIGS. 12A and 12B under the condition of no external stress acting at R=b is illustrated in FIG. 13 and shown with respect to the ratio of the radius b/a. Here again minimizing strain at more extended layers of the particle is important. In practice, this condition may be met by employing the ZnSeS alloy of the composition already discussed above as a first and/or one of possibly multiple layers of the colloidal quantum dot quantum well.

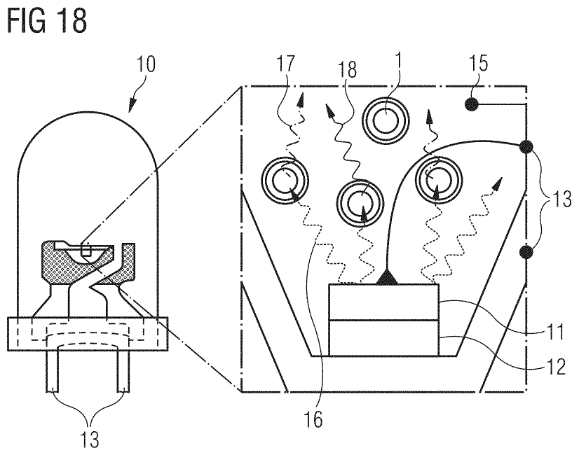

An exemplary embodiment of a light-emitting device 10 is illustrated in FIG. 18. The light-emitting device 10 comprises a semiconductor chip 11 configured to emit a primary radiation 16, for instance in the blue spectral range. For instance, the semiconductor chip is an LED chip. The semiconductor chip 11 is optionally arranged on a heat sink 12. The semiconductor chip is arranged in a cup-like portion of an electrode 13. A second electrode 13 is connected to the semiconductor chip via a bond wire so that during operation an electrical voltage can be applied between the electrodes resulting in a radiative recombination of charge carriers in the semiconductor chip.

The light-emitting device 10 further comprises a plurality of quantum dot structures 1. The quantum dot structures are embedded in a host matrix 15, for instance an encapsulation material like a silicon matrix material. For instance, the host-material 15 completely covers the semiconductor chip and at least partly fills the cup-like portion of electrode 13. The quantum dot structures absorb at least part of the primary radiation and re-emit a secondary radiation of a larger wavelength. In particular, some of the quantum dot structures are arranged in direct contact to the semiconductor chip.

Thus, the host-material with the quantum dot structures forms a radiation conversion element. For instance, the radiation conversion element includes two or more different types of quantum dot structures. For example, a first type is configured to emit a first secondary radiation 17 in the red spectral range and a second secondary radiation 18 in the green spectral range. In this example, the light-emitting device may emit the blue primary radiation as well as the red and green secondary radiation, so that the light-emitting device may emit a mixed radiation which may appear white to the human eye.

Departing from the exemplary embodiment shown in FIG. 18, the quantum dot structures 1 may also be used to form a radiation conversion element which is formed as a prefabricated platelet that is subsequently arranged on the semiconductor chip. Furthermore, other types of packages may be used, for instance premold packages. Of course, the quantum dot structures may also be used for devices with semiconductor chips mounted on a carrier, such as a circuit board or a submount.

In the following various exemplary embodiments of methods for the production of GaP-containing quantum dots are described. The methods may also be adapted to produce quantum dots based on InGaP and other III-V-compound semiconductor materials.

Furthermore, alternative indirect methods of synthesis may also apply. These methods are based on cationic exchange processes, which can be performed multiple times and create nanoparticles with desired crystallographic structures including those that do not occur in nature. Their resultant crystallographic phase imitates that of the template. For example, the formation of wurtzite GaP might result in more strongly absorbing nanoparticles compared to zinc blende analogs.

For example, the wurtzite crystal phase may be obtained by generating a related wurtzite material such as hexagonal InP or InZnP in a preceding step. These materials may then be conveniently converted to GaP, for instance by total or partial cation exchange with an appropriate Ga precursor. This method may also be used in order to produce InGaP, which might be potentially more useful.

Alternatively, cubic GaP may be converted to hexagonal GaP post-synthesis by inducing a crystal phase change using a “digestive ripening” technique.

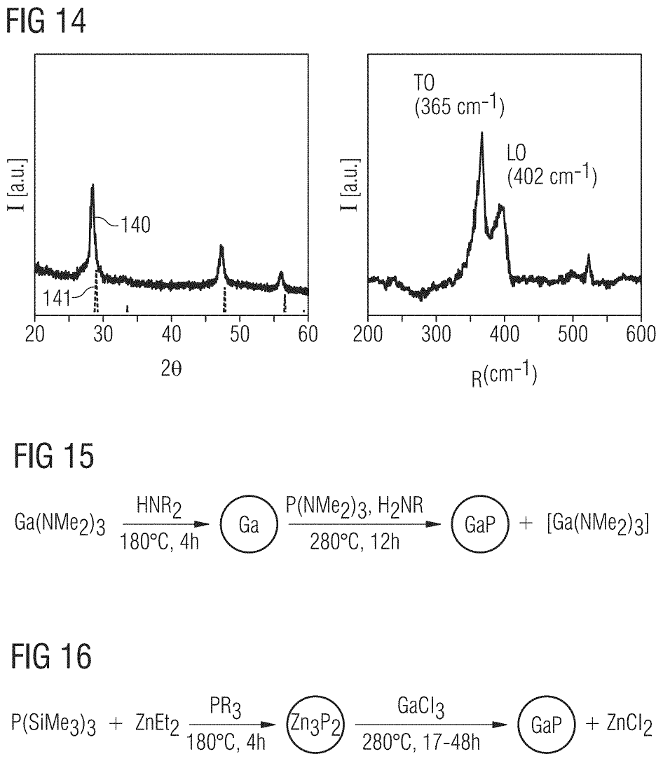

Gallium phosphide nanocrystals may be synthesized by the reduction of aminogallane precursors using dialklyamines at temperatures from 275° C. to 285° C. The reduction step produces a grey precipitate that reacts with dimethylaminophosphine, phosphorus trichloride, or tris(trimethylsilyl)phosphine in amine solution. Depending on the structure of the dialkylamine or the presence of n-alkylamines, the particle size can be tuned. In some cases, the order of addition proved important to gain size control and obtain a crystalline GaP product. The optical absorption spectrum of GaP is weakly absorbing near the band edge, as expected from the indirect band gap of the zincblende structure. The crystallinity is evident from FIG. 14 showing the powder X-ray diffraction peaks. The intensity I in arbitrary units (a.u.) is plotted against 2θ for GaP quantum dots (zincblend) (140) and a GaP reference (141). The Raman spectrum shows the intensity I in arbitrary units (a.u.) plotted against the Raman shift in cm⁻¹. The Raman spectrum shows clearly resolved transverse optical (TO) and longitudinal optical (LO) phonon modes of a phonon-confined crystal supports a highly crystalline, GaP quantum dot.

Gallium phosphide nanocrystals may also be obtained following exchange of cadmium ions in cadmium phosphide nanocrystals. Exchange of the cadmium ions for gallium ions may be accomplished by heating the nanocrystals in tri-n-octylphosphine and gallium chloride at 150° C. The conversion to GaP is clearly visible from the evolution of the optical spectrum and the appearance of reflections from the cubic GaP lattice in the X-ray diffraction pattern.

According to an exemplary embodiment, GaP nanoparticles are formed. Trioctylamine (10 mL, 22.9 mmol) was loaded into a three-neck round bottom flask and equipped with a reflux condenser, septa and a glass housing for a thermocouple. Separately, tris(dimethylamino)gallium-dimer (80 mg, 0.20 mmol) and dioctylamine (4.0 mL, 24.8 mmol) were loaded into a 20 mL vial equipped with a septum. Tris(dimethylamino)phosphine (130 mg, 0.80 mmol), trioctylamine (10 mL, 22.9 mmol), and hexadecylamine (2.0 g, 8.3 mmol) are loaded into a 20 mL vial and equipped with a septum. On a Schlenk line, the round bottom flask was brought to 280 ° C. Upon reaching the reaction temperature, the gallium precursor is injected into the round bottom flask and stirred for 1-2 min. Later, the desired phosphorus precursor is injected into the reaction mixture and the reaction runs for 20 hrs. Upon completion, the GaP nanocrystals are precipitated with methanol and centrifuged. The supernatant is discarded and the residue is suspended in toluene. Two more cycles of methanol/toluene are used to remove any residual organic byproducts.

According to an exemplary embodiment, GaP nanorods are formed. Octadecene (21 mL, 65 mmol) is loaded into a three-neck round bottom flask and equipped with a reflux condenser, septa and a glass housing for a thermocouple. Separately, tris(dimethylamino)gallane (75 mg, 0.19 mmol), tris(trimethylsilyl)phosphine (93.2 mg, 0.37 mmol) and dioctylamine (3.40 mL, 11.2 mmol) are loaded into a 20 mL vial equipped with a septum. On the Schlenk line, the round bottom flask is brought to 280° C. Upon reaching the reaction temperature, the gallium and phosphorus precursors are injected into the round bottom flask. The reaction is allowed to run for 2 days. Upon completion, the GaP nanocrystals are precipitated with methanol and centrifuged. The supernatant is discarded and the residue is suspended in toluene. Two more cycles of methanol/toluene are used to remove any residual organic byproducts.

FIG. 15 illustrates the reaction resulting in GaP. According to a further exemplary embodiment, the synthesis of GaP is obtained via Cation Exchange from Zinc Phosphide. The corresponding reaction is illustrated in FIG. 16.

Diethylzinc (98 mg, 0.79 mmol), tris(trimethylsilyl)phosphine (142 mg, 0.57 mmol), and trioctylphosphine (4.155 g, 5.0 mL, 11.21 mmol) are loaded into a three-neck round bottom flask equipped with two septa and a thermowell adapter. The mixture is brought to 200° C. on the Schlenk line. Separately, gallium (III) chloride (557 mg, 3.16 mmol) is dissolved in trioctylphosphine (4.155 g, 5.0 mL, 11.21 mmol) in a 20 mL vial. At 2.5 hours of reaction time, the gallium mixture is taken up with a syringe and quickly injected to the zinc phosphide mixture. The reaction is allowed to run overnight. Upon completion the reaction is transferred to an air-free glovebox. The nanocrystals are precipitated using methyl acetate and centrifuged. The supernatant is discarded and the residue is suspended in toluene. Two more cycles of methyl acetate/toluene are used to remove any residual organic byproducts. The final nanocrystal sample is kept in toluene.

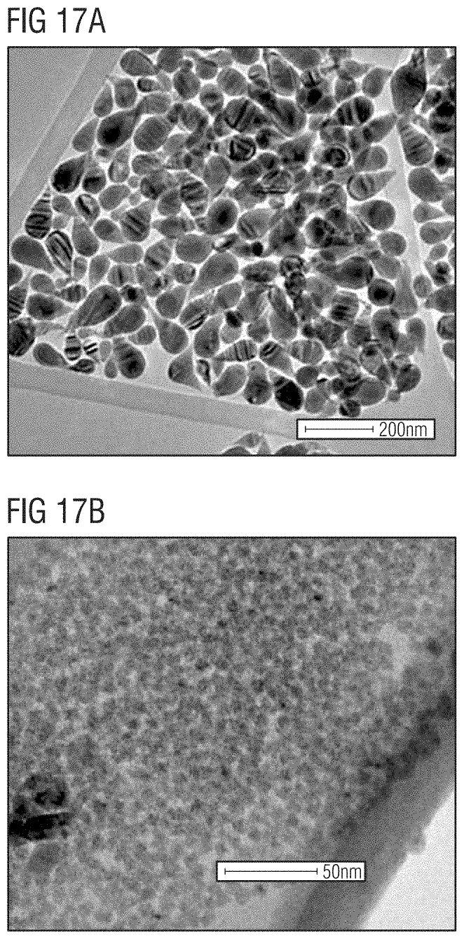

FIG. 17A depicts a TEM image of GaP particles synthesized using a Redox method. GaP particles produced using cation exchange is shown in FIG. 17B. These Figures prove that parameters of the nanoparticles, for instance their size, may be tuned by the way they are produced.

The methods described above may be used to form the described quantum dot structures, for instance.

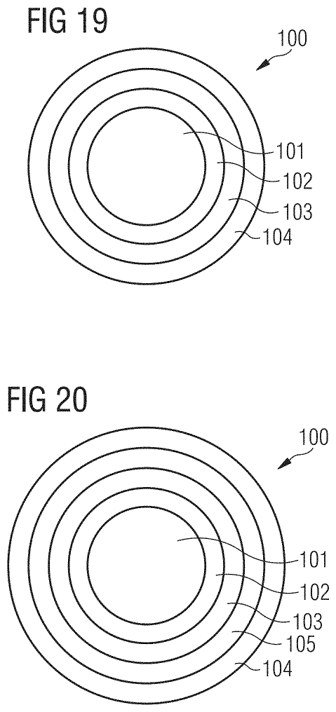

FIG. 19 shows a quantum dot structure 100 comprising a core 101, an intermediate region 102 at least partially, preferably completely, surrounding the core 101, a shell 103 at least partially, preferably completely, surrounding the intermediate region 102 and a passivation region 104 at least partially, preferably completely, surrounding the shell 103. In particular, the core 101, the intermediate region 102, and the shell 103 and the passivation region 104 are in direct contact to the adjacent core, region or shell, respectively.

The core 101, the intermediate region 102 and the shell 103 comprise or consist of a III-V-compound semiconductor material. The III-V-compound semiconductor material may comprise a minor component, for example, a catalyst remaining in the III-V-compound semiconductor material. The minor component may be a chemical element, for example, Zn. In particular, the minor component does not determine the light-emitting or light-absorbing character of the III-V-compound semiconductor material. For example, the core 101, the intermediate region 102 and the shell 103 comprise or consist of binary, ternary or quaternary phosphides such as InP, GaP, InGaP or InZnGaP. In particular, the core 101, the intermediate region 102 and the shell 103 are free of Cd.

The passivation region 104 comprises or consists of a II-VI-compound semiconductor material, for example, binary or ternary zinc compounds such as ZnS, ZnSe or ZnSeS.

The quantum dot structure 100 can have a symmetric or an asymmetric shape, for example, a spherical shape as depicted in the exemplary embodiment of FIG. 19 or a dot-in-rod shape.

The quantum dot structure 100 depicted in FIG. 19 can be a quantum dot structure 100 with a core-shell geometry. Thus, the core 101 is the light-emitting region, while the shell 103 is an absorbing region of the quantum dot structure 100. The core 101 may comprise or consists of InP or In₁₋ₓGaₓP with 0≤x≤1, in particular with 0≤x≤0.63. The shell 103 may comprise or consist of GaP or In₁₋ₓGaₓP, in particular with 0.63≤x≤1. Thus, the core 101 has a direct bandgap and the shell 103 has an indirect bandgap.

The intermediate region 102 can comprise a graded alloy of the III-V-compound semiconductor material of the core 101 and the III-V-compound semiconductor material of the shell 103. For example, the intermediate region 102 comprises In₁₋ₓGaₓP with 0≤x≤1. Thus, the intermediate region 102 may have a lattice constant between the lattice constants of the core 101 and the shell 103 to facilitate lattice matching and to reduce lattice strain between the core 101 and the shell 103.

In particular, the core 101 comprises or consists of InP and has a diameter of between at least 2 nm and at most 10 nm, for example. The core 101 is in direct contact to the intermediate region 102 comprising or consisting of In₁₋ₓGaₓP with 0≤x≤1 with a thickness of between at least 0.25 nm and at most 10 nm, for example. The intermediate region 102 is in direct contact to the shell 103 comprising or consisting of GaP with a thickness of between at least 2 nm and at most 20 nm, for example.

Alternatively to the core-shell geometry, the quantum dot structure 100 depicted in FIG. 19 can be a quantum dot structure loo with a quantum well geometry. Thus, the core 101 and the shell 103 are absorbing regions, while the intermediate region 102 is the light-emitting region of the quantum dot structure loft The intermediate region 102 may comprise or consists of InP or In₁₋ₓGaₓP with 0≤x≤1, in particular with 0≤x≤0.63. The core 101 and the shell 103 may comprise or consist of GaP or In₁₋ₓGaₓP with 0≤x≤0.63, preferably with 0≤x≤0.15. Thus, the intermediate region 102, the core 101, and the shell 103 may all have a direct bandgap, while, in particular, the intermediate region may also have an indirect bandgap.

In particular, the core 101 comprises or consists of In₁₋ₓGaₓP with 0≤x≤0.63 and has a diameter of between at least 2 nm and at most 10 nm, for example. The core 101 is in direct contact to the intermediate region 102 comprising or consisting of InP with a thickness of between at least 0.25 nm and at most 4 nm, for example. The intermediate region 102 is in direct contact to the shell 103 comprising or consisting of In₁₋ₓGaₓP with 0≤x≤0.63 with a thickness of between at least 2 nm and at most 20 nm, for example.

FIG. 20 shows the quantum dot structure 100 of FIG. 19 comprising an intermediate passivation region 105 between the shell 103 and the passivation region 104. The intermediate passivation region 105 comprises a II-VI-compound semiconductor material that can be the same or a different material than the II-VI-compound semiconductor material of the passivation region 104.

The invention is not restricted to the exemplary embodiments by the description on the basis of the exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A quantum dot structure comprising:
a core comprising a III-V-compound semiconductor material;
an intermediate region comprising a III-V-compound semiconductor material at least partially surrounding the core;
a shell comprising a III-V-compound semiconductor material at least partially surrounding the core and the intermediate region; and
a passivation region comprising a II-VI-compound semiconductor material at least partially surrounding the shell.

2. The quantum dot structure according to claim 1, wherein the core and/or the intermediate region and/or the shell comprises In₁₋ₓGaₓP with 0≤x≤1.

3. The quantum dot structure according to claim 1, wherein the core and/or the intermediate region and/or the shell comprises In₁₋ₓGaₓP with 0≤x≤0.63.

4. The quantum dot structure according to claim 1, wherein the intermediate region comprises a graded alloy of the III-V-compound semiconductor material of the core and the III-V-compound semiconductor material of the shell.

5. The quantum dot structure according to claim 1, wherein the intermediate region and the shell comprise at least one chemical element not present in the core, and wherein a concentration of the chemical element in the intermediate region increases at least partially from core to shell.

6. The quantum dot structure according to claim 1, wherein the core, the intermediate region, and the shell form a quantum well structure.

7. The quantum dot structure according to claim 1, wherein the core and/or the intermediate region and/or the shell is free of Cd.

8. The quantum dot structure according to claim 1, wherein the core and/or the intermediate region and/or the shell comprises Zn.

9. The quantum dot structure according to claim 1, wherein the intermediate region comprises a smaller bandgap than the core and the shell.

10. The quantum dot structure according to claim 9, further comprising an intermediate passivation region comprising a II-VI-compound semiconductor material between the shell and the passivation region.

11. A light-emitting device comprising:
a semiconductor chip configured to emit primary radiation; and
a conversion element comprising a plurality of quantum dot structures according to claim 1,
wherein the quantum dot structures are configured to convert at least part of the primary radiation into secondary radiation.

12. The light-emitting device according to claim ii, wherein some of the quantum dot structures are arranged in direct contact with the semiconductor chip.

13. A method of producing a quantum dot structure, the method comprising:
forming a core comprising a III-V-compound semiconductor material;
forming an intermediate region comprising a III-V-compound semiconductor material at least partially surrounding the core; and
forming a shell comprising a III-V-compound semiconductor material at least partially surrounding the core and the intermediate region.

14. The method of claim 13, wherein forming the core comprises performing a cationic exchange process.

15. The method of claim 13, wherein forming the core comprises converting a wurtzite phosphide material into wurtzite InGaP, GaP or InZnGaP.

16. The method of claim 13, wherein forming the core comprises converting a cubic InGaP, GaP or InZnGaP into hexagonal InGaP, GaP or InZnGaP by a crystal phase change.

17. The method of claim 13, wherein forming the core comprises using an aminophosphine.

18. The method of claim 13, wherein forming the core comprises producing InGaP nanocrystals, GaP nanocrystals or InZnGaP nanocrystals by reducing an aminogallane precursor.

19. The method of claim 13, further comprising forming a passivation region comprising a II-VI-compound semiconductor material at least partially surrounding the shell.
